(19) United States
(12) Patent Application Publication
(10) Pub. No.: US 2005/0147753 A1
(43) Pub. Date: Jul. 7, 2005

(54) Material deposition system and a method for coating a substrate or thermally processing a material in a vacuum

(75) Inventor: Gary L. Smith, McMurray, PA (US)

Correspondence Address: THE WEBB LAW FIRM, P.C., 700 KOPPERS BUILDING, 436 SEVENTH AVENUE, PITTSBURGH, PA, 15219, US

(73) Assignee: Kurt J. Lesker Company, Clairton, PA (US)

(21) Appl. No.: 11/009,957

(22) Filed: Dec. 10, 2004

Related U.S. Application Data
(63) Continuation-in-part of application No. 10/111,297, filed on Apr. 22, 2002, now Pat. No. 6,830,626.
(60) Provisional application No. 60/161,094, filed on Oct. 22, 1999.

(51) Int. Cl. C23C 16/00

(52) U.S. Cl. 427/249.1

(57) ABSTRACT

Disclosed is a material deposition system for depositing material onto a surface of a substrate. The system includes a first body element with an interior cavity and an exit aperture extending through the first body element, and a second body element having an interior cavity and an exit aperture extending through the second body element. The interior cavity of the second body element contains the material, and the exit aperture of the second body element is spacially separated from and in fluid communication with the exit aperture of the first body element. The first body element and the second body element are rotatable, such that the exit apertures of the first body element and the second body element can be aligned and misaligned. A material deposition system with novel aperture spacing and separation and methods of coating a substrate and thermally processing a deposition material are also disclosed.

### CROSS REFERENCE TO RELATED APPLICATIONS

This application is a continuation-in-part of U.S. patent application Ser. No. 10/111,297, filed Apr. 22, 2002, which claims priority of PCT/US00/29099, filed Oct. 20, 2000 which also claims priority of U.S. patent application Ser. No. 60/161,094, filed Oct. 22, 1999, all of which are incorporated herein by reference in their entirety.

### BACKGROUND OF THE INVENTION

1. Field of the Invention

The present invention relates to material deposition systems for coating or depositing a material upon an object or substrate, together with methods of coating a substrate or otherwise thermally processing a material in a vacuum, and in particular to a material deposition system for use in the evaporation or sublimation of material onto substrates and methods of coating a substrate and thermally processing a material in the field of physical vapor deposition.

2. Background of the Invention

Coating a substrate typically involves vaporizing a material in a vacuum by some heated means such that the volatilized contents condense onto a substrate that is at a lower temperature. Within the field of physical vapor deposition (PVD), the body, which contains, energizes, and emits the deposition material, is generally referred to as the deposition source. The various sub-component functions of a traditional deposition source, such as chemical containment, output flux, active emission profile and temperature feedback have not been presented with respect to a removable and separate deposition crucible technology. Specifically, the existence of a removable large area and linear configuration deposition crucible for fabrication of organic, molecular or low temperature materials has not been presented in the prior art.

In one new technology area of physical vapor deposition, the deposition of organic or low temperature materials, occurs on a large width substrate of plastic film to create flexible flat panel displays. Deposition sources in general perform some of the required functions, but do not allow for the high volume production compatibility of immediately removable and replaceable deposition crucibles with self contained functions such as chemical containment, large area configuration, feedback and active emission flux profile shaping.

In general, during the fabrication of devices comprised of organic, or low temperature, based materials, such as organic-based LED displays, organic-based lasers, organic-based photo-voltaic cells, organic-based transistors, or organic-based integrated circuits, chemicals or compounds are typically applied to the substrate in a vacuum using point source crucibles, or modified point source, crucibles. When a crucible is heated, the chemicals vaporize and emit from the point source crucible in a generally cosine-shaped emission plume. A generally flat substrate is then typically held in a fixed position or rotated within the emission plume with a planar side of the substrate facing the point source to receive the deposition. A fraction of the vaporized chemicals deposit onto the presented face of the substrate, condensing and thus forming a thin film coating.

In the production of organic or low temperature materials based displays, or electronic devices, a thin, flat, film-like substrate is coated on at least one side of the substrate. The substrate material may be plastic, polymeric, glass or other suitable surface upon which to grow a smooth organic film. The substrate is typically planar in configuration, and is constrained by the general limitations of deposition sources to produce uniform, or flat, coatings. Three dimensional, curved or any other non-planar substrates have not been used due to the difficulty of producing the required emission flux patterns. To obtain an acceptable coating, portions of the emission plume are selected to achieve a uniform emission for the substrate size. Most round or point sources produce a cosine-shaped output generally curved downward from a central maximum value. The uniform portion of the emission plume is inadequate for most industrial uses. The invention deposition crucible is capable of tailoring a user-desired emission plume profile. This emission plume increases the overall efficiency for industrial uses over the prior art.

In some applications, modified point sources are used to produce a gaussian (non-uniform) flux distribution. Examples of modified point sources include R.D. Mathis-type boats, Knudsen cells, or induction furnace sources. Traditional deposition source structures are designed for the evaporation of metals and salts in the range of 800° C. to 1300° C. These are inappropriate for evaporating organic-based chemicals in the range of 100° C. to 500° C. Organic-based chemicals are molecules. Excessive heat will degrade the molecular chemistry and decompose the chemicals to an undesirable form. These deposition sources generally utilize a small portion of the total source emission flux. The remaining fraction of emission flux, deposited upon other components within the vacuum system may degrade the quality of the film on the substrate. This generally requires that the vacuum system be taken out of service for cleaning. Vaporized chemicals frequently condense, alter, and occlude the point source crucible exit aperture. The condensed materials may fall back into the crucible's heated interior, spit onto the substrate, or otherwise adversely affect the deposited film. The difficulty to control the exposure of the sensitive chemistries to high temperature surfaces of traditional deposition source structures leads to chemical decomposition.

Point source and modified point source crucibles only produce uniform films when flux angles are kept small. These sources do not exhibit extended flux uniformity along any axis. Flux angles are measured from an axis concentric with the crucible output aperture. The only way to keep the flux angle small enough to produce an acceptable coating uniformity is to increase the separation distance between the point source crucible and the receiving side of the substrate. When the distance from the source to substrate is increased in order to enhance coating uniformity, a smaller portion of the emitted vapor may condense upon the desired region of the substrate, degrading material utilization and effective deposition rate. Film uniformity is an important characteristic of organic layers utilized for photonic and electronic applications. If the organic-based films are not often maintained at a 95 percent or higher level of uniformity, fabricated devices may not operate properly. Increasing the deposition source volatilization rate is an inefficient means to compensate for the reduced deposition rate associated with separation distances in large area molecular deposition production systems.

Point-type sources primarily limit substrates to several centimeters in width, or diameter. Current requirements for the fabrication of organic based displays involve the uniform coating of substrates with dimensions of 0.5 to 1.0 meters in width or diameter. Point-type sources have emission outputs similar to the functions such as cosineⁿ power, where n is generally greater than 2.0. Such output characteristics restrict the ability of the source to successfully deposit functional organic or low temperature films upon substrates at sizes generally greater than 30 centimeters. Traditional deposition sources deliver as little as 5% of the crucible loaded material to the substrate in a usable form. Low material utilization efficiency and deposition rates fail to address requirements for long term production applications.

Another problem associated with prior art open crucible designs is that the emission profile is not constant over the life of the contained deposition chemistry. As the contained material is volatilized to grow coatings upon a substrate, the level of the chemistry drops within the crucible. This change in the line of sight from the chemistry level in the deposition crucible to substrates further tightens the emission profile and may reduce the coating uniformity upon the substrate as production coating proceeds.

For point-style sources, the separation distance to achieve a 95% uniform or higher can be predicted. If this uniformity requirement is applied to a 30 centimeter square substrate, for example, then a separation distance of approximately 60 centimeters may be required. By comparison, a 60 centimeter square substrate would require a proportional 120 centimeter separation distance which is generally impractical for vacuum systems size, performance, and cost. Vacuum chambers must be made larger to accommodate the increased separation distances, requiring more powerful and more costly vacuum pumps.

Typical point-style sources for organic, or low temperature, materials as applied to larger substrates greater than approximately 30 centimeters exhibit increasingly unacceptable material utilization efficiencies. Prior art has demonstrated 95% material waste. Many organic light emitting diode (OLED) display chemistries cost thousands of dollars per gram and effect competitive pricing of completed devices. A deposition crucible which emits material to a substrate with a 5% material utilization efficiency (95% of the material wasted) represents a three times increase in the cost of required deposition materials due to material waste as compared to a crucible design which exhibits a 70% material utilization efficiency (30% of the material wasted).

Film growth rates of organic-based materials are typically expressed in single Angstroms per second. The rate of film growth is greatly reduced and is inversely proportional to the square of the separation distance between the source and the substrate. In the first example, if the effective deposition rate is 16 angstroms per second, then in the second example the deposition rate is 4 angstroms per second. The change in deposition rate reduces the productivity of the deposition by a factor of 4. There is a substantial waste of expensive chemicals, since an increase in separation distance decreases material utilization efficiency from the deposition source crucible.

The vaporized organic material which does not participate in productive substrate coating is deposited on interior walls and shielding of the vacuum chamber, which demands that the vacuum chamber be removed from productive service and cleaned more frequently. Cleaning is expensive because some chemicals, such as those used to produce organic displays are toxic as well as expensive. Costs are further exaggerated because point or modified point source crucibles generally contain approximately 10 to 100 cubic centimeters of OLED chemistry, as limitations related to chemistry residency time and thermally induced degradation of many molecular materials occurs. Therefore, a limited number of substrates can be coated before the vacuum system must be vented to atmosphere, the vacuum chamber cleaned, the crucibles refilled, and the vacuum chamber re-evacuated.

Deposition technology in the prior art does not address the film quality as a function of deposition rate. Prior deposition technology largely concerns itself with the deposition of non-temperature-sensitive atomic metal and inorganic vapors. With the advent of molecular physical vapor deposition (PVD) and molecular beam epitaxy (MBE), the quality of many of the requisite films grown are directly related to deposition rate and deposition chemistry temperature. In the case of aluminum trishydroquinoline (AlQ₃), an important organic light emitting diode (OLED) device component material, the material will not produce smooth films at increased deposition rates when the material spits clusters onto the substrate instead of emitting from the crucible as a uniform vapor. The use of lower deposition rates produces more acceptable and functional films. At lower effective deposition rates, the background contamination level of a vacuum processing system as measured by its vacuum pressure level is at a higher relative level, which further contaminates the depositing film. This is detrimental to the performance of traditional organic LED devices. In order to fabricate a sufficient high purity organic thin film, the background pressure level must be low in comparison to the deposition rate of the organic material upon the substrate. The effective deposition rate decreases as the source to substrate separation distance is increased in order to produce an acceptably uniform film with increasing substrate dimensions.

Prior art deposition source and crucible designs do not provide for ability to deliver increased effective deposition rate to the substrate with increasing substrate size due to the limiting properties of critical organic materials, such as aluminum trishydroquinoline (AlQ₃). As substrate dimensions increase, the effective deposition rate falls while the background contamination level remains somewhat constant, thus producing films which are comprised of increasingly higher levels of contaminants. The prior art deposition source or crucible technology may produce inferior films and device performance upon the large substrates associated with large-scale production operations.

In the prior art point source types of deposition sources and crucibles, substrates are often rotated within the source output emission in order to randomize the deposition of the materials to the substrate and enhance the coating uniformity to an acceptable level. Production manufacture of organic LED (OLED) display devices does not favor rotational motion as a means of enhancing coating uniformity. In the cases of large area batch glass coating or roll-to-roll web coating, the substrate motion frequently involves linear translation of the substrate with respect to the deposition source. This requires that the deposition source may have to coat the entire substrate width, often to a 600 mm dimension, without the enhancing effect of randomized substrate motion. The deposition source in these cases must be capable of depositing an acceptably uniform film at an acceptably productive deposition rate directly from the deposition source or crucible to the entire substrate width dimension, which is not characteristic of the prior art.

Further, the prior art does not indicate linear configuration deposition sources or crucibles for either molecular or low temperature volatilizing materials with ability to provide a user desired and active tunable emission profile, precision rate control, and enhanced film quality to large area substrates. Previous linear configuration deposition sources have only attempted to stretch out conductive-resistive boat concepts. Prior art conductive-resistive deposition source concepts lack the ability to achieve the emission pattern and material utilization efficiency produced by the invention deposition crucible assembly. Due to the inability of previous prior art deposition sources or crucibles to actively profile the emission output, the material utilization efficiencies of these crucibles have been less than 50%.

Prior art point-style and linear configuration deposition sources for metals evaporations do not provide for features such as an easily removable materials containing crucible from the deposition source structure, or from the heater. Still further, prior art designs for linear configuration deposition sources have relied upon a conductive-resistive body that generates the heat required to volatilize the contained chemistry. These are high current devices, often requiring from 100 to 500 amps of current to produce emissions from the deposition source. By requirement of power circuit resistance, linear or point source deposition sources have been required to be firmly connected to the driving electrical circuit with significant clamping and heavy gauge cables. This is always the case with resistance-based baffled box-type evaporation boats or of linear metals evaporation sources. This has made it difficult to provide for a linear configuration deposition source with a separate and readily removable crucible subassembly apart from an outer structure of the deposition source.

Prior art deposition source and crucible design does not provide for a linear configuration crucible assembly, particularly for organic materials depositions, which is readily separable from the outer structure of the deposition source. Also, prior art deposition crucibles are either simple open containers placed into a heated zone, or they are integrated with the deposition source structure for requirements of heating and do not retain identity as a separate or removable subassembly with respect to the deposition source structure. In the latter case, the term crucible does not apply, as this implies separability, ease of removal, and non-connection or light connection with the electrical circuit. Prior art deposition crucibles have not been described with characteristics of reduced operating current and increased operating voltage. Operation at reduced current enables the crucible to be operated with lowered requirements for connector and cabling size, as well as firm method of clamping to the source.

Prior art does not provide for a crucible design within a deposition source structure that is easily rotatable with respect to either the deposition source structure or the substrate. The prior art does not evidence linear or point-style deposition crucibles or sources with adjustability with respect to either of the deposition source structure or the target substrate. Still further, the prior art does not indicate the active control of crucible emission profile via the utilization of one or more variably dimensioned, or spaced, emission apertures to the point that there is intentional production of a delta-pressure between the crucible containing organic materials and the external environment, which produces an altered emission profile, for the purpose of achieving desired coating uniformity profiles and enhanced material utilization efficiencies. Also, the prior art does not indicate that the coating uniformity of organic materials to a substrate may be tailored to a process at a particular range of deposition rate.

Prior art deposition sources exhibit only passive control over source emission to the substrate. Baffling and other forms of subtractive shielding have been used in order to produce a sectioned portion of the source emission upon the substrate. The intent of passive emission profile control is to block sections of the deposition source emission from line of sight to the substrate. The blocked portion of the emission coats the shielding and is removed from productive deposition to the substrate. Prior art passive emission profile control only serves to degrade the material utilization efficiency of the deposition source.

Traditional open crucibles have open apertures of from 0.5 centimeter to several centimeters in diameter, and do not indicate the generation of emission profile control that allows for the custom matching of crucible output to produce uniform or other thickness type molecular coatings to non-planar substrates. In particular, the prior art has considered only planar substrate surfaces and has excluded 3-dimensional objects as potential substrates upon which to fabricate molecular display or thin film organic electronics circuits.

In one example according to the prior art, a point source crucible A, as shown in FIG. 1, or a modified point source crucible is utilized. When chemicals are heater, the chemicals vaporize and radiate away from the crucible A, through an exit aperture B, in a generally cosine-shaped emission plume C. A substrate D is then held in place in a fixed position or rotated within the emission plume C with a planar side E of the substrate D facing the crucible A. A certain amount of vaporized chemicals deposit on the planar side E of the substrate D, thus forming a film coating.

As shown in FIG. 2, flux angles α, β, and γ are measured from an axis N extending from the exit aperture of the point source crucible to lines L1, L2 and L3 representing the edge of the cosine-shaped plume C shown in FIG. 1. The only way to keep the flux angle small, such as the angle a shown in FIG. 2, is to greatly increase the separation distance, or throw distance, between the point source crucible A and the planar side E of a substrate, such as those substrates referred to by reference numerals D1, D2 and D3. For example, substrate D2 would need to be moved to the position of substrate D3 to be fully coated, while keeping the flux angle a constant. Such a move would increase the throw distance from TD2 to TD3. Similarly, if substrate D3 is moved to the position of substrate D1, i.e., from TD3 to TD1, then only a portion of substrate D3 would be uniformly coated. The coating uniformity is governed by the emission angle encompassed from the crucible to the desired coated dimensions of the substrate. This is determined by the source-to-substrate separation distance. The increased rate of deposition to the substrate when the substrate is positioned at the D1 position is also associated with poorer coating uniformity as the crucible emits a cosine-shaped flux. By keeping the emission angle to the outer dimensions of the substrate small, the central portion of the emission profile is utilized to produce a coating to the substrate. The coating uniformity falls off toward zero the further away from the crucible centerline that the substrate exposure extends. As coating uniformity is a critical parameter to provide functional devices for organic display and molecular electronics devices, emission angles must be kept small in order to maximize coating uniformity. Generally, 95% film uniformity is required in order to provide acceptable device performance.

As seen in FIG. 3, in a resistance-based evaporation source, the contained chemistry B is in direct contact with a conductive-resistive deposition source body A. Specifically, and according to the prior art, the source body A is provided and includes the contained chemistry B. Electrical contacts C are firmly affixed to the source body A, and using high-current cabling D, a current is applied to the source body A, and therefore the contained chemistry B. In this manner emitted material E is directed towards a substrate F. This prior art design does not include a separate crucible portion of the source, as it generally consists of a continuous molybdenum or tantalum body attached to the electrical contacts C. The passage of high current through the deposition source body A provides the heating necessary to volatilize the contained chemistry B, which is held in the interior cavity of this type of deposition source A. This type of deposition source does not have a separate crucible subassembly, and there is no provision for an easily removable crucible of contained chemistry from the deposition source structure.

Point-type sources include traditional round, point, or molecular beam epitaxy (MBE) designs (See FIGS. 4 and 5). In particular, FIG. 4 illustrates a simple open crucible A, such as a cylindrical crucible A with a large round aperture B. Heaters C, in the form of resistive wire elements, surround the crucible A and heat the crucible A, such that the contained chemistry D is emitted, as emitted material E, towards a substrate F, which may be fixed or rotating within the emitted material E stream. In addition, a thermocouple G may be used to sense the temperature of the crucible A. FIG. 4 indicates a typical deposition source crucible, which is removable from a support structure. The emission from such a large aperture B is generally of the form cosineⁿ, where n is >2.0. As mentioned in the discussions of FIGS. 1 and 2, the average emission falls off as either the substrate dimension increases or the source to substrate separation distance is decreased, which captures greater emission angles emanating from the crucible aperture. Accordingly, such a crucible design does not have the ability to actively control the profile of the deposition chemistry emission and is subject to source to substrate separation distance requirements as the only method to control the deposited thin film uniformity to the substrate.

An example of an MBE design is illustrated in FIG. 5, which also includes a crucible A, the aperture B, heaters C, contained chemistry D and thermocouple G. In addition, the contained chemistry D is emitted, as emitted material E, towards the substrate F. However, in this design, the aperture A is variably sized, with the crucible A having a neck portion H that gradually expands into a lip portion H, thereby providing a different emission profile. Further, the heaters C (or resistive wire elements) may be applied to the neck portion I, and second thermocouple J can be used to sense the lip portion H temperature of the crucible A. Such a crucible A typically emits deposition vapors in a profile function as discussed above. The source to substrate separation distance from the crucible aperture to the substrate receiving surface must be increased to maintain coating uniformity over successively larger substrates. This is done at the expense of reduced deposition rate, as compared to the invention deposition crucible.

### SUMMARY OF THE INVENTION

In order to solve the problems associated with the prior art, the present invention is directed to novel material deposition systems, crucible assemblies and methods of coating a substrate or thermally processing a material in a vacuum. It is, therefore, one object of the present invention to provide systems, assemblies and methods of coating a substrate or thermally processing a material that overcome the deficiencies in the prior art. In particular, the present invention provides control over new classes and ranges of low temperature and molecular materials, active emission profile control, reduced source-to-substrate separation distance, improved molecular film quality and device performance, prolonged life and higher materials utilization efficiency, increased substrate dimension coating capability, higher effective deposition rate, reduced cost of deposition materials and operations, reduced fabricated device costs, new substrate translational motions, such as linear transport and web coater compatibility, quick and easy removability of a separate crucible assembly from a fixed deposition source structure, reduced vacuum system maintenance requirements and costs, reduced cabling and power circuit hardware and costs, rotatability to aim deposition emissions in various directions and alignments relative to the deposition source structure and/or substrate, utilization of internal to external crucible delta-pressure to assist emission profiling, ability to coat 3-dimensional non-planar substrates as well as planar ones and improved control over emission or deposition rate as compared to traditional systems, crucibles and deposition source technologies.

The present invention is directed to a material deposition system for depositing material onto a surface of a substrate. The system includes a first body element having an interior cavity and at least one exit aperture extending through the first body element. The system further includes at least one second body element having an interior cavity and at least one exit aperture extending through the at least one second body element. The interior cavity of the at least one second body element contains the material, and the at least one exit aperture of the at least one second body element is spatially separated from and in fluid communication with the at least one exit aperture of the first body element. The first body element and the second body element are rotatable with respect to each other, such that the at least one exit aperture of the first body element and the at least one exit aperture of the second body element can be aligned and misaligned with respect to each other.

The present invention is also directed to a material deposition system for depositing material onto a surface of a substrate, where the system includes at least one body element having an internal cavity configured to contain a material, a wall with a wall thickness and a substantially enclosed upper surface. The body element further includes a plurality of apertures extending through the upper surface of the at least one body element and forming a pattern along the upper surface, and the exit apertures have an open dimension (D) and a separation spacing (P). The open dimension (D) and the separation spacing (P) are one of fixed and variable dimensions. The plurality of exit apertures have an open dimension (D) in the range of about ⅕ and about 5 times the wall thickness of the at least one body element, and the plurality of exit apertures have a separation spacing (P) in the range of about 1.0 and about 20 times the open dimension (D) of the at least one body element.

The present invention is further directed to a method of coating a substrate in a deposition material system having a crucible with a plurality of exit apertures extending therethrough, a deposition source structure and a vacuum system. The method includes the steps of: (a) positioning at least one of the deposition source structure and the crucible within the vacuum system; (b) positioning at least one deposition chemistry element within the crucible; (c) positioning at least one substrate in fluid communication with the deposition chemistry element; (d) heating the deposition chemistry element to volatilize the deposition chemistry element and emit material; (e) exposing at least a portion of the at least one substrate to material emitted from the heated deposition chemistry element through a plurality of exit apertures in operational communication with at least one of the deposition source structure and the crucible; and (f) removing the crucible from the deposition source structure and vacuum system through at least one openable end of the deposition source structure.

The present invention is further directed to a method of thermally processing a deposition material contained in a crucible and a deposition source structure in a vacuum system. The method includes the steps of: (a) positioning at least one of the deposition source structure and the crucible within the vacuum system; (b) positioning deposition material to be thermally processed in the crucible through an openable end of the deposition source structure and the crucible; (c) heating the deposition material in a thermal processing procedure to at least one of process, clean, de-gas and fractionally distill the deposition material; and (d) removing at least one of the deposition source structure and crucible from the vacuum system.

In a further aspect of the present invention, a crucible is provided. The crucible includes at least one body element having an internal cavity configured to contain a material, a wall with a wall thickness and a substantially enclosed upper surface and a plurality of apertures extending through the upper surface of the at least one body element and forming a pattern along the upper surface, wherein the exit apertures have an open dimension (D) and a separation spacing (P), wherein the open dimension (D) and the separation spacing (P) are one of fixed and variable dimensions;wherein the plurality of exit apertures have an open dimension (D) in the range of about ⅕ and about 5 times the wall thickness of the at least one body element; and wherein the plurality of exit apertures have a separation spacing (P) in the range of about 1.0 and about 20 times the open dimension (D) of the at least one body element.

The present invention, both as to its construction and its method of operation, together with the additional objects and advantages thereof, will best be understood from the following description of exemplary embodiments when read in connection with the accompanying drawings.

### BRIEF DESCRIPTION OF THE DRAWINGS

FIG. 1 is a side view of a single point source crucible according to the prior art;

FIG. 2 is a side view of the prior art crucible of FIG. 1 with increasingly larger substrates positioned adjacent the crucible;

FIG. 3 is a schematic view of a resistance-based evaporation source according to the prior art;

FIG. 4 is a side view of an open crucible assembly with a large aperture according to the prior art;

FIG. 5 is a side view of an open crucible assembly with a small aperture according to the prior art;

FIG. 6 is a schematic view of one embodiment of a crucible and material deposition system according to the present invention;

FIG. 7 is end cross sectional view of a further embodiment of a crucible and material deposition system according to the present invention;

FIG. 8 is an end cross sectional view of a further embodiment of a crucible and material deposition system according to the present invention;

FIG. 9 is an end cross sectional view of a further embodiment of a crucible and material deposition system according to the present invention;

FIG. 10 is a side cross sectional view of a further embodiment of a crucible and material deposition system according to the present invention;

FIG. 11 is a perspective view of one embodiment of a portion of a crucible according to the present invention;

FIG. 12 is a perspective view of a further embodiment of a portion of a crucible according to the present invention;

FIG. 13 is a perspective view of a further embodiment of a portion of a crucible according to the present invention;

FIG. 14 is a graph illustrating substrate film thickness versus lateral aperture position for a substrate coated using a crucible according to the present invention; and

FIG. 15 is a graph illustrating substrate film thickness versus substrate deposition width for a substrate coated using a crucible according to the present invention.

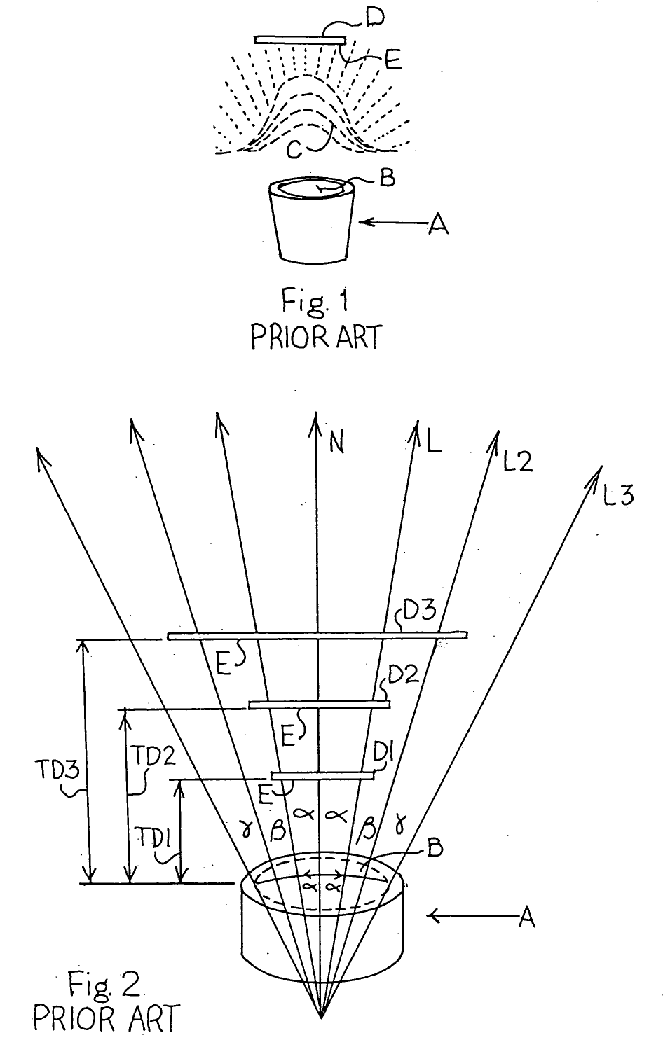

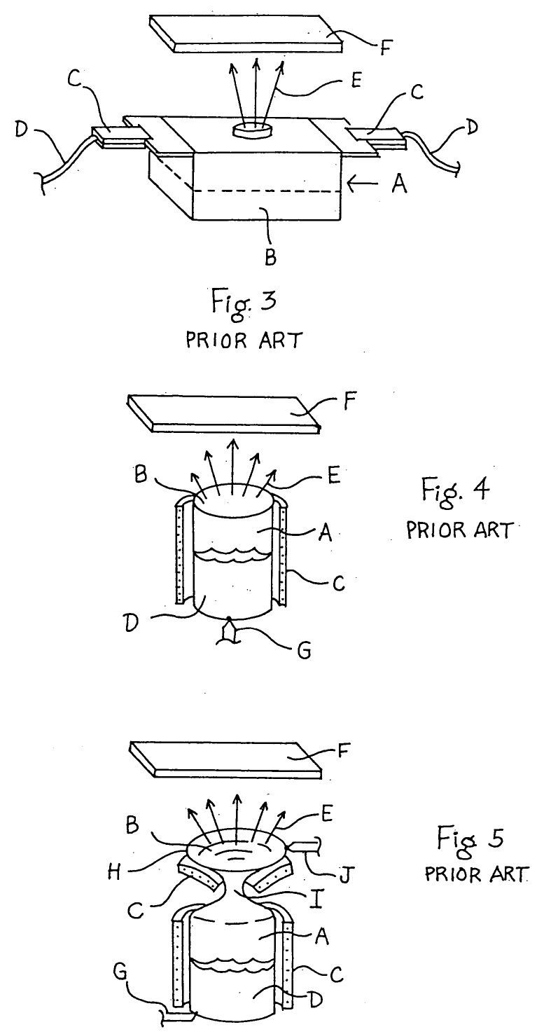

### DETAILED DESCRIPTION OF THE PREFERRED EMBODIMENTS

Other than in the operating examples or where otherwise indicated, all numbers or expressions referring to quantities of ingredients, reaction conditions, etc., used in the specification and claims are to be understood as modified in all instances by the term “about.” Various numerical ranges are disclosed in this patent application. Because these ranges are continuous, they include every value between the minimum and maximum values. Unless expressly indicated otherwise, the various numerical ranges specified in this application are approximations.

For purposes of the description hereinafter, the terms “upper”, “lower”, “right”, “left”, “vertical”, “horizontal”, “top”, “bottom”, “lateral”, “longitudinal” and derivatives thereof shall relate to the invention as it is oriented in the drawing figures. However, it is to be understood that the invention may assume various alternative variations and step sequences, except where expressly specified to the contrary. It is also to be understood that the specific devices and processes illustrated in the attached drawings, and described in the following specification, are simply exemplary embodiments of the invention. Hence, specific dimensions and other physical characteristics related to the embodiments disclosed herein are not to be considered as limiting.

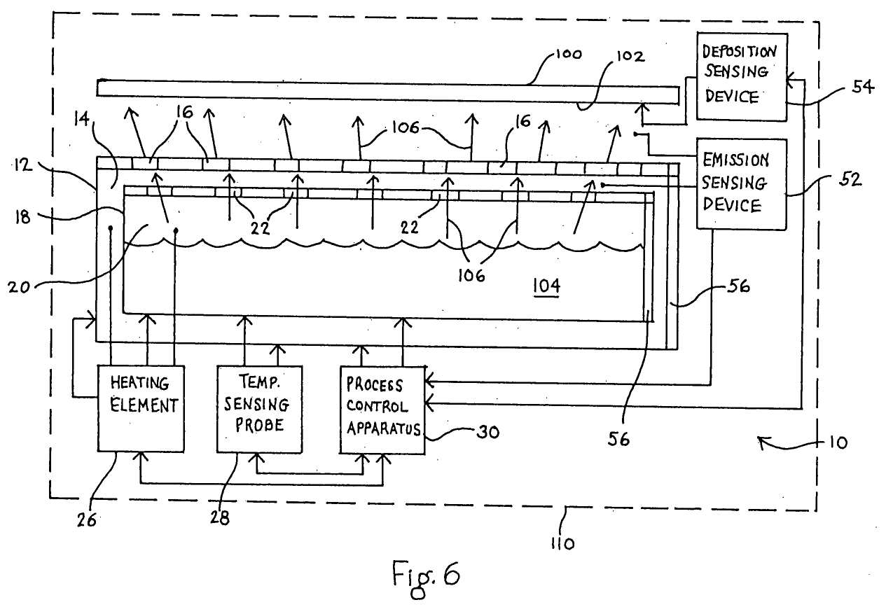

The present invention is directed to a material deposition system 10, as well as various methods for coating or otherwise interacting with a surface 102 of a substrate 100 in a physical vapor deposition system, or thermally processing a material 104 in a vacuum. Various embodiments of the presently-invented material deposition system 10 are illustrated in FIGS. 6-13. In particular, the material deposition system 10 includes various components and subcomponents which contain the material 104, which will be emitted, as an emitted material 106, towards the surface 102 of the substrate 100. In this manner, the emitted material 106 is deposited upon the surface 102, as is known in the art.

In one embodiment, the material deposition system 10 includes a first body element 12 having an interior cavity 14 and at least one exit aperture 16 extending through the first body element 12. In addition, the system 10 includes at least one second body element 18, also having an interior cavity 20 and at least one exit aperture 22 extending through the second body element 18. The interior cavity 20 of the second body element 18 is constructed so as to contain the material 104. In addition, the exit aperture or apertures 22 of the second body element 18 are spacially separated from and in fluid communication with the exit aperture or apertures 16 of the first body element 12. In addition, the first body element 12 and the second body element 18 are rotatable or positionable with respect to each other, such that the exit apertures 16 of the first body element 12 are alignable or misalignable with respect to the exit apertures 22 of the second body element 18.

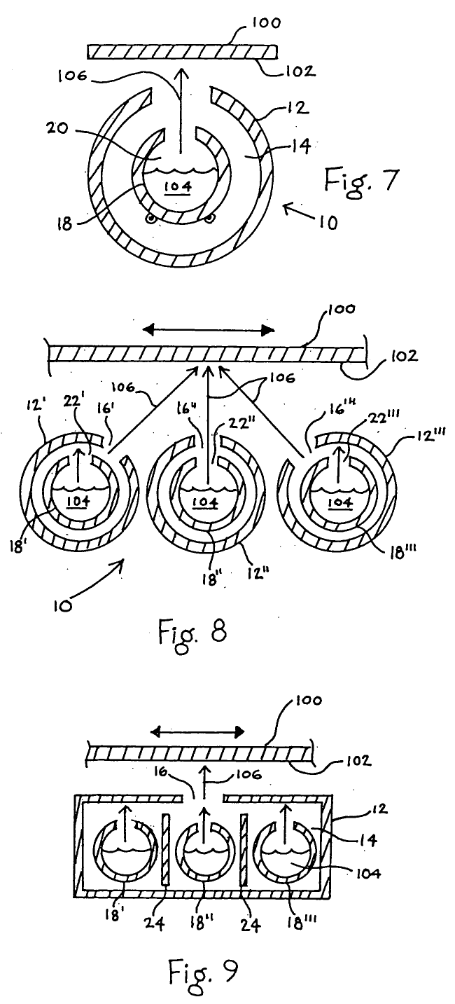

As seen in FIG. 7, and in one embodiment, the first body element 12 and the second body element 18 are longitudinally extending members in a nested relationship. Further, the first body element 12 and the second body element 18 may be in the form of a tube, such that the second body element 18 is easily rotatable within the first body element 12. The alignment and misalignment functionality of the first body element 12 and the second body element 18 allow a new and novel control of the emitted material 106, and accordingly the resulting film deposited upon the surface 102 of the substrate 100.

This unique controllability may also be achieved using multiple first body elements 12 and/or second body elements 18. For example, as illustrated in FIG. 8, a plurality of first body elements 12 and second body elements 18 are utilized. By allowing the exit apertures 22 of the second body element 18 to remain static, and by rotating one or more of the first body element 12, the emitted material 106 can be specifically directed to a specified and focused portion of the surface 102 of the substrate 100.

In the embodiment illustrated in FIG. 8, three second body elements 18′, 18″ and 18′″ are respectively nested within three first body elements 12′, 12″ and 12′″. The exit apertures 22′, 22″ and 22′″ of the second body elements 18′, 18″ and 18′″ remain aligned with respect to each other and point generally toward the surface 102 of the substrate 100. However, the exit apertures 16′ and 16′″ of the first body element 12′ and the first body element 12′″ are oriented or “pointed toward” the same focused portion of the surface 102 of the substrate 100. Again, this allows the presently-invented material deposition system 10 to provide varying film uniformity and other novel characteristics to the surface 102 of the substrate 100. In addition, it is also envisioned that each of the second body elements 18′, 18″ and 18′″ can include different materials 104, which would result in a different emitted material 106. This, in turn, allows varying materials 104 to be deposited upon the surface 102 of the substrate 100, which provides even greater flexibility in the process.

In another embodiment, as illustrated in FIG. 9, the second body elements 18′, 18″ and 18′″ are all located within a single first body element 12. As with the arrangement of FIG. 8, the arrangement of FIG. 9 also illustrates the ability to focus the emitted material 106 onto the surface 102 of the substrate 100. In addition, as discussed above, a different material 104 may be placed in each of the second body elements 18′, 18″ and 18′″. Further, thermal baffling 24 may be used to separate the various second body elements 18′, 18″ and 18′″.

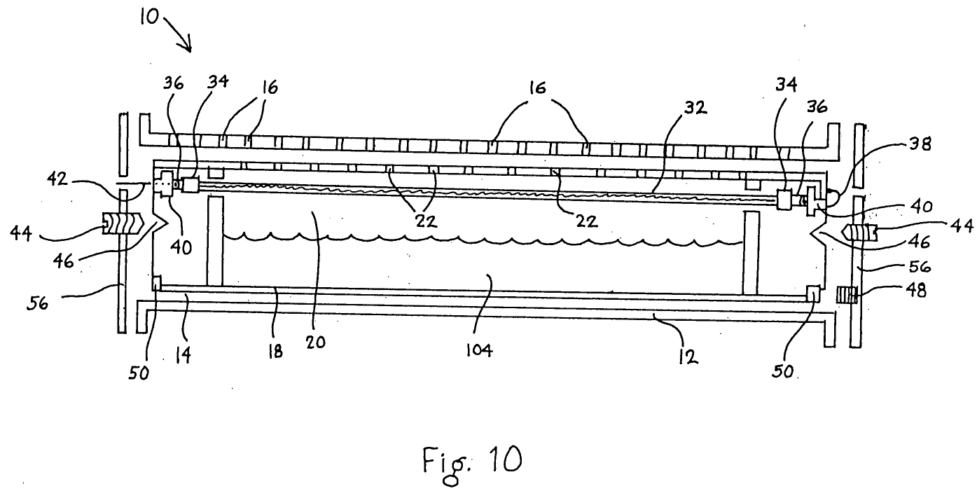

The material deposition system 10 of the present invention may also include a heating element 26. This heating element 26 is in physical communication with the first body element 12 and/or the second body element 18. Further, this heating element 26 can directly heat the material 104 in the second body element 18, or alternatively, it may indirectly heat the material 104 in the second body element 18. For example, various heating elements 26 are envisioned, some of which are in direct contact with the material 104, and some of which heat the space around the material 104 or the second body element 18. In one embodiment, and as illustrated in FIG. 10, the heating element 26 extends within the inner cavity 20 of the second body element 18. Accordingly, this heating element 26 heats the second body element 18, which subsequently heats the material 104.

In one embodiment, the first body element 12 extends along a substantially longitudinal axis, and the heating element 26 is positioned within the interior cavity 20 of the second body element 18 and extends along a substantially longitudinal axis, which is parallel with the longitudinal axis of the second body element 18. Such an arrangement is illustrated in FIG. 10.

In another embodiment, the material deposition system 10 includes a temperature sensing probe 28. The temperature sensing probe 28 is in communication with the first body element 12, the second body element 18 and/or the material 104. Through this communication and contact, the temperature sensing probe 28 is capable of sensing the temperature of the first body element 12, the second body element 18 and/or the material 104 contained in the second body element 18. As with the heating element 26, the temperature sensing probe 28 may be in direct or indirect contact with the first body element 12, the second body element 18 and/or the material 104 in the second body element 18. It is envisioned that this temperature sensing probe 28 may be a thermocouple, a Type “K” thermocouple, a resistance temperature detector, an optical pyrometer, etc.

The system 10 may also include a process control apparatus 30 to control the various components and subcomponents of the system 10. In one embodiment, the process control apparatus 30 is in communication with the heating element 26, the temperature sensing probe 28, the first body element 12, the second body element 18, or some other component of the system 10. In operation, the process control apparatus 30 may provide temperature control of the first body element 12, the second body element 18 and, indirectly, the material 104 in the second body element 18. In another embodiment, the process control apparatus 30 is in communication with the temperature sensing probe 28 and receives feedback signals from the temperature sensing probe 28 in order to appropriately control the system 10.

It is envisioned that the heating element 26 may also be an electrical circuit that is configured to receive power from electrical connections. For example, the heating element 26 may be a heating lamp 32 connected to a termination button tab 34 and a spring contact part 36. On one end of the heating lamp 32, a lead wire 38 is attached to the first body element 12 and/or the second body element 18. On the other end of the heating lamp 32, a seal 40 can be used to engage with the second body element 18, however the seal 40 would allow an electrical connection 42 to extend therethrough in order to provide electricity to the heating lamp 32. See FIG. 10. In this embodiment, one or more cone screws 44 may be provided on an assembly for attachment to or mating with a cone screw notch 46. The cone screw notch 46 is disposed upon the first body element 12 and/or the second body element 18. In particular, the cone screw notch 46 accepts the cone screw 44 to establish radial and/or vertical positioning of the second body element 18 to the first body element 12 or other housing in the system 10.

Similarly, in this embodiment, a pin 48 may be provided. The pin 48 could be pressed into a corresponding pin notch 50, which is located on the first body element 12 and/or the second body element 18, for example, an axial end of the second body element 18. The engagement of the pin 48 with the pin notch 50 allows for positioning of the rotational position of the second body element 18 within the system 10. In addition, the pin 48 and pin notch 50 engagement allows the user to align the exit aperture 22 of the second body element 18 and the exit aperture 16 of the first body element 12.

As discussed above, in one embodiment, the first body element 12 and the second body element 18 both include a plurality of exit apertures 16, 22, for example multiple exit apertures 22 and at least one exit aperture 16. These exit apertures 16, 22 may extend substantially longitudinally along and through the first body element 12 and the second body element 18, respectively. These exit apertures 16, 22 can be aligned, or alternatively, misaligned, with each other. It is this alignment and misalignment that provides one novel aspect of control to the system 10 and the emitted material 106.

Another means of controlling the pattern, concentration, etc. of the emitted material 106 upon the surface 102 of the substrate 100 is to provide variably spaced and/or variably sized (or shaped) exit apertures 16, 22. For example, the exit apertures 16, 22 may be positioned with respect to each other in order to provide a desired emission flux pattern and/or a desired coating profile on the surface 102 of the substrate 100. Therefore, this desired flux pattern and coating profile can be obtained through variably sized exit apertures 16, 22; variably shaped exit apertures 16, 22; variably spaced exit apertures 16, 22; aligned exit apertures 16, 22; and/or specifically positioned exit apertures 16, 22.

It is envisioned that the material 104 may be an organic material, a low-temperature volatilizing material, etc., as is known in the art. In addition, the system 10 may also include an emission sensing device 52 for sensing the emission of the emitted material 106 through the exit apertures 22 of the second body element 18 and/or the exit apertures 16 of the first body element 12. Accordingly, the rate of material 104 volatilization from the first body element 12 and/or the second body element 18 can be determined. It is envisioned that the emission sensing device 52 may be a quartz crystal oscillator, an optical emission monitor, an electron emission monitor, an atomic emission monitor, an atomic absorption monitor, a molecular emission monitor, a molecular absorption monitor, etc.

In order to provide still further control, the system 10 can include a deposition sensing device 54. This deposition sensing device 54 senses the deposition of the emitted material 106 upon the surface 102 of the substrate 100. As discussed above in connection with the emission sensing device 52, the deposition sensing device 54 can help in determining the rate of material volatilization from the first body element 12 and/or the second body element 18. It is envisioned that the deposition sensing device may be an optical transmission monitor, an optical absorption monitor, etc.

In yet another and novel aspect of the present invention, either the first body element 12 and/or the second body element 18 can be provided with an access port 56 for providing access to the interior cavity 14 of the first body element 12 and/or the interior cavity 20 of the second body element 18. For example, this access port 56 may be positioned on an axial end of the first body element 12 and/or the second body element 18. Still further, the access port 56 may be openable, removably attachable, removable or otherwise provide the functionality of access to the interior cavity 14, 20.

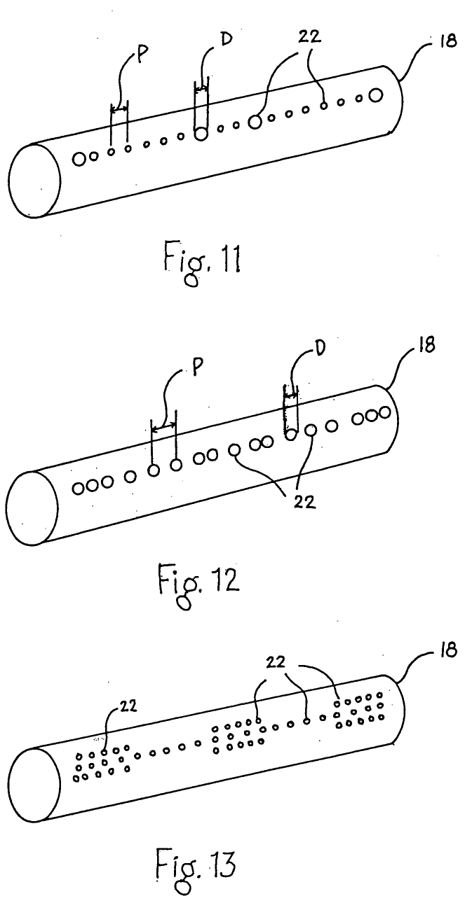

In another aspect of the present invention, and as illustrated in FIGS. 11-12, a material deposition system 10 is provided having at least one body element, such as the second body element 18 discussed above, having a substantially enclosed upper surface 58. The plurality of exit apertures 22 extend through this upper surface 58. However, in this embodiment, the exit apertures 22, which extend to the upper surface 58 of the body element 18, form a pattern along the upper surface 58. These exit apertures have an open dimension D and a separation spacing P. The open dimension D and the separation spacing P can have fixed or variable dimension with respect to each other.

In one preferred embodiment, the exit apertures 22 have an open dimension D in a range of about ⅕ and about five times the wall thickness of the body element 18. Further, the exit apertures 22 have a separation spacing P in a range of about 1.0 and about twenty times the open dimension D of the body element 18. Still further, the exit apertures 22 extend along a majority portion of the upper surface 58 of the body element 18.

The system 10 described hereinabove may also include all of the components and subcomponents of the system 10 described above in connection with the first body element 12 and the second body element 18. For example, the system 10 described in this embodiment may include the access port 56, the heating element 26, the temperature sensing probe 28, the process control apparatus 30, the emission sensing device 52, the deposition sensing device 54, etc. In addition, the body element 18 may be attached to a support fixture that provides reduced thermal conductance and separation of the body element 18 from different and further components of the material deposition system 10.

It is envisioned that the body element 18 may be a substantially longitudinally extending member, and may further be substantially symmetrical about a longitudinal axis. In one embodiment, the body element 18 is fabricated from a thermally conductive metal material, a thermally conductive ceramic material, etc. Further, the exit apertures 22 may be positioned in a substantially symmetrical manner with respect to a center line of the body element 18.

In one preferred embodiment, the open dimension D of the plurality of exit apertures is in the range of about 0.03 cm and about 0.15 cm. Further, the plurality of exit apertures 22 may have a total open hole area of less than about 1.0 cm² per 35.0 cm of body element 18 length. A portion of the plurality of exit apertures 22 may include an open dimension D less than the wall thickness of the body element 18.

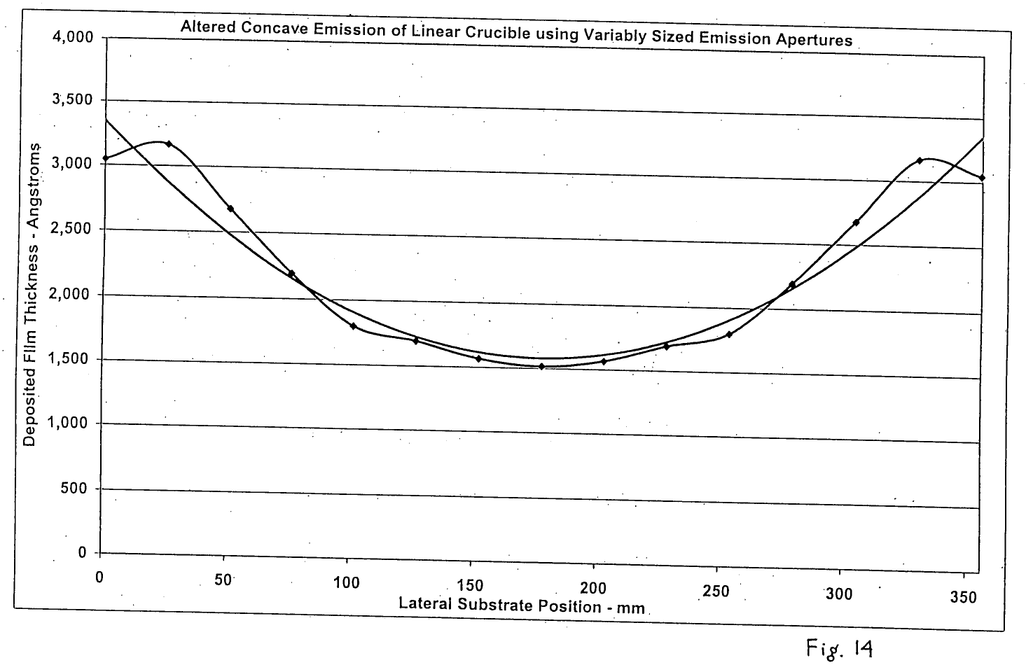

FIGS. 11-13 illustrate various embodiments of this variable exit aperture 22 spacing and sizing, which allows the user to obtain a specified and controllable emitted material 106, film thickness and uniformity on the surface 102 of the substrate 100, etc. By using the variable exit aperture 22 spacing and exit aperture 22 sizing, a better film thickness on the surface 102 of the substrate 100 may be obtained. For example, FIG. 14 illustrates the altered concave emission of the system 10 using these variably sized exit apertures 22. In particular, FIG. 14 represents a plot of the film thickness on the surface 102 of the substrate 100 as a function of lateral position on the upper surface 58 of the body element 18. In this example of variable sizing of the apertures 22, the apertures 22 are provided every 0.2 inches over the centered 14-inch emission area. The apertures 22 are all 0.025 inches in diameter, except for the two end apertures 22 are 0.047 inches in diameter, and the center aperture 22 is 0.034 inches in diameter. The resulting improved emission profile is illustrated in FIG. 14.

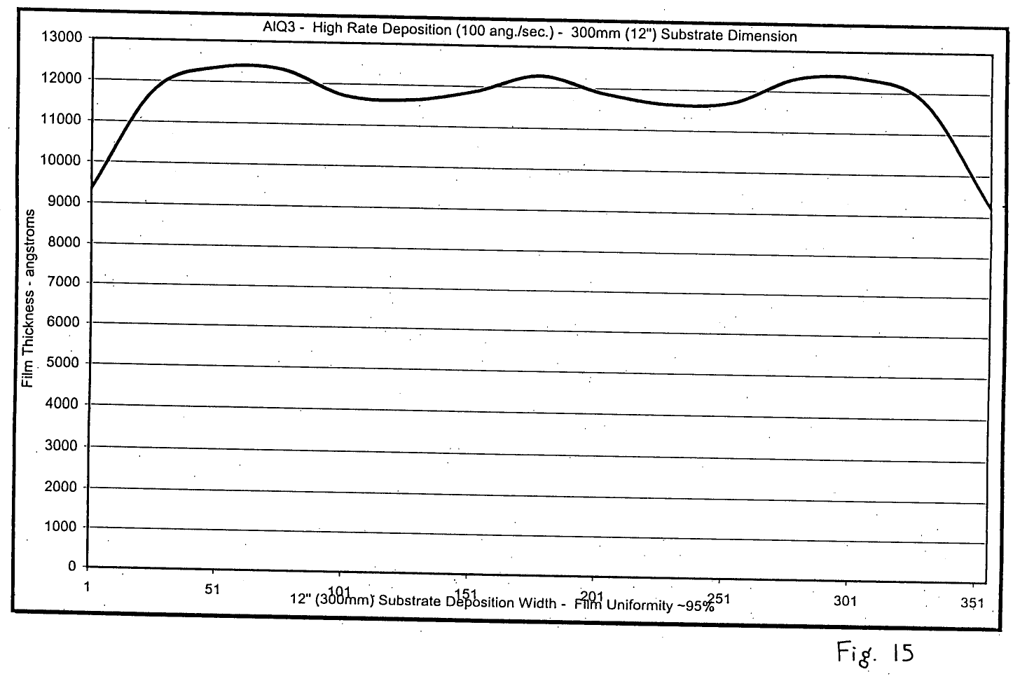

In a high-rate deposition application, film uniformity is greatly increased using this variable spacing and/or sizing. For example, as illustrated in FIG. 15, a plot is provided of the film thickness on the surface 102 of the substrate 100 as a function of the substrate 100 deposition width. In particular, in one example of variable spacing of the apertures 22, the apertures 22 are all 0.025 inches in diameter, but the spacing between apertures 22 varies between 0.109 inches and 0.498 inches. Specifically, in this example, the spacing gradually increases between the apertures 22 when moving from an end aperture 22 to a center aperture 22. The resulting and improved film uniformity using this variable spacing arrangement is illustrated in FIG. 15.

The present invention is also directed to a method of coating the substrate 100 in the deposition material system 10. The system 10 includes a crucible (such as the second body element 18) with a plurality of exit apertures 22 extending therethrough. In addition, the system 10 includes a deposition source structure in a vacuum system 110. While the vacuum system 110 is discussed as a separate system than the material deposition system 10, it may be considered as integral to the material deposition system 10 in the area of physical vapor deposition processes as is known in the art. Accordingly, the vacuum system 110 may be an ancillary to, integral with or otherwise in operative communication with the material deposition system 10. In this embodiment, the method includes the steps of: positioning the deposition source structure and the crucible 18 within the vacuum system 110; positioning a deposition chemistry element, such as material 104, within the crucible 18; positioning one or more substrates 100 in fluid communication with the deposition chemistry element 104; heating the deposition chemistry element 104 to volatilize the deposition chemistry element 104 and emit material, in the form of emitted material 106; exposing at least a portion of the one or more substrates 100 to the emitted material 106, which is emitted through the exit apertures 22; and removing the crucible 18 from the deposition source structure and the vacuum system 110 through an openable end, such as the access port 56 of the deposition source structure.

In a further embodiment, the crucible 18 is reintroduced into the deposition source structure and the vacuum system 110 through the access port 56, and the crucible 18 may include the same deposition chemistry or material 104, a different material 104, or some further productive coating material element. This subsequent material 104 is then heated and the substrate 100 is exposed to this emitted material 106, as discussed above. In order to provide further control over the system 10, relative motion may be provided between the emitted material 106 and the substrate 100, which provides a desired coating uniformity.

The present system 10 may also be implemented in the form of a method of thermally processing a deposition material 104 using the aforementioned body element 18 (or crucible) and a deposition source structure in a vacuum system 110. This method includes the steps of: positioning the deposition source structure and the crucible 18 within the vacuum system 110; positioning the deposition material 104 to be thermally processed in the crucible 18 through an openable end, such as the access port 56, of the deposition source structure and the crucible 18; heating a deposition material 104 in a thermal processing procedure to process, clean, degas and fractionally distill the material 104; and removing the deposition source structure and the crucible 18 from the vacuum system 110. As discussed above in connection with the previous method, using the access port 56, the same, additional or different material 104 can be subsequently reintroduced into the system 10 and the vacuum system 110 for further processing.

While in one preferred embodiment, the first body element 12 and the second body element 18 are in the form of a tube, this general tube shape is not necessary. In particular, the cross-sectional shape of the first body element 12 and/or second body element 18 can be square, rectangular, oval, arched, crescent or polygonal. It is general preferable, however, that the crucible extend in a linear or longitudinal direction, which allows the first body element 12 and/or the second body element 18 to deposit to a large substrate 100. For example, the long axis of the body element 12, 18 can be aligned in the direction of the width of the receiving substrate 100, which translates in relative motion through the emission profile of the body element 12, 18. The substrate 100 often travels through the emission presented by the body element 12, 18, however, any of the components of the system 10 and/or the substrate 100 may move with respect to various axes of the substrate 100, or by a combination of motions between the body elements 12, 18 and the substrate 100. This movement allows the coating of the substrate 100 to achieve the desired area coverage and coating uniformity.

While, as discussed above, the body element 12, 18 may receive thermal input from many different sources, whether directly or indirectly, and whether positioned within or without the body element 12, 18, a heating circuit is often desirable, since it exhibits high resistance and low current characteristics and allows for greatly reduced power connector fixturing and cabling size. In some cases, elimination of the requirement for mechanical fixation or clamping to a simple physical contact may be enabled with the use of reduced ranges of current that are required to control the body element 12, 18.

In one embodiment, the rate of emission of the material 104 is monitored by an associated quart crystal monitor crystal, which senses the emitted material 106. The sensed emission rate is communicated to intelligent controls equipment, such as the process control apparatus 30, which then applies a corresponding level of energy input from a power supply and a heat source, such as the heating element 26, to create the desired emission rate. Alternative feedback sensors may be used, as discussed above. This enables the system 10 to operate in a rate-controlled mode and deliver coating material 104 to the receiving substrate 100 at a desired rate of emission or deposition. Such an operational mode is particularly desirable for deposition to a moving web substrate 100 in the roll coaters, in which the moving substrate 100 receives a known rate of deposition at a given speed and exposure time to the body element 12, 18.

As discussed above, the body element 18 or crucible 18 may be held in place by an outer deposition source structure, which in one embodiment may be the first body element 12 or associated attachment structures. The overall structure provides a means for holding and aligning the crucible 18 within the deposition system 12, and with respect to the substrate 100, in order to allow for controlled source-to-substrate separation distance and deposition of the vapors emitted from the crucible 18 subassembly to the substrate 100. Also as discussed above, the deposition source structure (or the first body element 12, the second body element 18 or some other associated housing or structure) includes the access port 56, which is easily removable and allows for ease and speed of both insertion and removal of the crucible 18 subassembly from the deposition source structure or first body element 12.

By rotating the crucible 18 (the second body element 18) and/or the first body element 12, the associated exit apertures 22, 16 may be aligned or misaligned with respect to the deposition source structure (or first body element 12) and the substrate 100 in order to achieve a variety of functions, such as line-of-sight baffling of the deposition chemistry to the substrate 100, as may be required for materials prone to deposition of rough films with evidence of clustering or spitting from the crucible 18. Accordingly, the crucible 18 may be aligned to the deposition source and substrate 100 when this deposition chemistry allows in order to reduce vapor residency time within the deposition source structure and enhance deposition rate and direction. The deposition crucible 18 (or second body element 18) and the deposition source structure (or first body element 12) are independently rotatable with respect to the substrates 100, which allows for aiming the emitted material 106 with respect to the substrates 100. This proves of particular value in the use of multiple materials 104 to a common substrate 100 position, such as when performing co-deposition or tri-deposition to produce multi-composite thin films.

The radial position of the second body element 18 may be centered or altered with respect to the deposition source outer structure, such as the first body element 12, in order to induce thermal gradient patterns favorable to the deposition of various molecular or low temperature chemistries. The exit aperture 16, 22 may be aligned, but also may be misaligned to provide the additional line-of-sight baffling discussed above, as is often the case with electronic material aluminum trishyeroquinoline (AlQ₃).

One particular benefit of the system 10 of the present invention, is that the nature of molecular emission profiles and the ability to actively alter such profiles has not been provided in the prior art, either for systems 10 or subassemblies therein. In particular, with the use of a linear configuration deposition crucible with a uniform emission aperture, whether as a uniform slit or as a plurality of uniform holes, the emission pattern is not uniform or flat with respect to either the longitudinal direction of the emission slit of the crucible or with respect to the receiving substrate. The film produced in the substrate is very nonuniform. In one test, the deposition made from such a deposition crucible exhibited a maximum of approximately 7,500 angstroms across the central 10 cm of the deposited substrate width when used at a source-to-substrate distance of 5 cm. The deposition thickness fell off to approximately 1,200 angstroms at +/−18 cm from either side of the center of the substrate. This level of nonuniformity resembles that produced by a point source, but with a broader shape. As with the point source style crucibles, the area of acceptable uniformity must be sectioned from the overall emission output profile to achieve the required coating uniformity across the entire substrate quality surface. This degrades the material utilization efficiency and deposition rate. In the cases of deposition of the molecular electronic material aluminum trishyeroquinoline (AlQ₃) from a linear configuration source with a uniform aperture pattern, the central region of +/−1.75 cm of the total 30 cm deposited width is the only acceptable section of the deposited emission from which to fabricate a 95% uniform film to a planar substrate surface.

With respect to the present invention and material deposition system 10, the system 10 can deliver a deposition pattern that is reversed to traditional deposition source emission profiles. Through the use of active control over the emission flux profile through the use of variably dimensioned and/or spaced apertures 16, 22, the material 104 utilization efficiency delivered to a substrate 100 is significantly enhanced. The system 10 of the present invention is capable of performing with approximately 70% material utilization efficiency (with only 30% material waste) at a 5 cm source-to-substrate distance. This reduces waste or unusable material 104 to less than half of the other types of linear configuration deposition sources, which are not removable as separate subassemblies. This level of material utilization performance also reduces by ⅔ the material waste associated with traditional point source crucible and deposition source technology. These gains improve comparatively as substrate dimensions further increase.

As discussed above, the use of control, variably sized apertures 16, 22 and/or variably spaced exit apertures 16, 22, work together with pressure to allow for the creation of an emission profile that may be custom tailored for deposition of uniform films to a variety of 2-dimensional planar and 3-dimensional curved or non-planar surfaces. As illustrated in FIG. 12, the generally concave versus convex emission pattern shape may be influenced out to the last several centimeters of the subassembly, thus further enhancing material utilization efficiency.

As discussed above in connection with FIG. 13, a removable first body element 12 and/or second body element 18 can be used in conjunction with a tuned emission profile that creates a 95% uniform film to large 300 mm substrate centered to the emission apertures 16, 22. This presents unprecedented levels of deposition uniformity from a large area deposition crucible, and the material utilization efficiency is greatly increased and a majority of the deposition crucible output may be used directly to produce a uniform deposition across a wide substrate width, and with very little portion of the emission being excluded from the participation in the deposition process.

The above-discussed temperature sensing probe 28 may be in the form of a thermocouple, which is attached to the outer surface of the first body element 12, the second body element 18, an inner surface of the body element 12, 18 or within the inner cavities 14, 20 of the body elements 12, 18. The feedback from the thermocouple is communicated to the process control apparatus 30, and in one embodiment, a control power supply may deliver electrical power to the surrounding deposition source structure, which, in turn, imparts thermal energy to the first body element 12 and/or the second body element 18 to heat the material 104. The heating process is monitored in terms of the temperature produced to the material 104 by one of direct or indirect contact with the various components in the system. Accordingly, the system 10 can be operated in a temperature-controlled mode, allowing for temperature programming of components of the system 10 relative to the thermocouple output, in order to produce either a desired temperature or temperature-based processing program. The heating element 26 may impart thermal energy to the first body element 12, the second body element 18, the material 104, etc. to perform various temperature profile routines, such as one of stable temperature control, temperature ramping in controlled degrees per unit time or commanding the system to a new temperature set point with controlled ramp. It is often the case that in the preparation of molecular deposition chemistries, vacuum degassing or cleaning of the material 104 at a given elevated temperature for a specific period of time is required. In addition, deposition of certain molecular materials occurs with certain temperature limitations due to the potential for degradation of the chemistry above a certain temperature.

Also as discussed above, by using any of the temperature sensing probe 28, the emission sensing device 52 and the deposition sensing device 54, in communication with the process control apparatus 30, the system 10 may be controlled, and specifically, control of the rate and temperature is achieved. This allows for relationships to be established between the emission rate and the temperature measurement in the system 10. Frequently, both the emission rate control and temperature control functionalities are required in order to successfully provide production coating. In one embodiment, the first body element 12 and/or the second body element 18 may be “idled” at a known temperature when not operating to produce a desired emission rate. Also, as is frequently the case, quartz crystal monitors may fail and stop sending emission rate data for control over the rate of volatilization of the material 104. In this event, a switch to temperature control is required in order to maintain the production coating operations until either a new quartz crystal monitor sensor can be placed on line. Another clean crystal may be switched on line from a plurality of crystals to indicate the crucible emission rate following a crystal failure, as is known in the case of managing an array of quartz crystals. In a special case with deposition of organic molecular materials, the failed crystal may be cleaned of its deposited organic-molecular material and placed back on line to again begin feedback of the emission rate to the intelligent controls or process control apparatus 30 after it is cleaned of the deposited material and rendered sensitive to again measure the rate. In particular, organic materials are different from metals in connection with a quartz crystal sensor in that they may be liberated from a quartz sensor surface by revolatilization of material therefrom. This may be accomplished by thermal projection upon the crystal surface, or ion beam, or plasma may provide the energy input required to volatilize the molecular chemistry from the crystal face. Temperature control may be used between crystal availabilities to maintain coating operations. A new crystal may be surpassed or alternated with a previously-used and cleaned crystal or a quick switching function may be performed between multiple available crystals, such that the use of temperature control as a backup method to maintain process control is either reduced or eliminated in the management of quartz crystal sensors, while performing coating operations.

In this manner, the present invention provides a material deposition system 10 and associated methods that provide novel capabilities in the practice of depositing organic materials to large area substrates 100 in a more productive and valuable manner. The present system 10 provides materials 104 to the substrates 100 with unrivaled levels of material utilization efficiency and with film quality and smoothness not previously available in point source style crucibles. The system 10 allows for improved productivity, improved reliability and reduced costs in the practice of deposition of organic and low-temperature materials 104. By application of the greater material utilization efficiency and superior film uniformity presented per deposition source size, the present invention performs longer and provides more productive coating to the substrate 100 per the amount of charge chemistry, together with the reduced requirement for the size of the containing vacuum system 110. As the total residency time of molecular chemicals at elevated temperature within a vacuum system may generate increased levels of molecular decomposition, the present invention and system 10 performs productive coatings with a reduced charge of molecular chemistry. A smaller amount of charge chemistry may provide for an increased number of coated substrates 100, which provides for a reduced amount of expensive chemistry being paced at risk at one time and a reduction in materials consumption costs in the production of organic devices. This, in turn, enables the production of higher quality films and better performing organic devices. Further, lower vacuum system 110 costs are associated with the production processes of the present invention, since less vacuum space is required in the performance of the deposition process.

The present invention and system 10 improves the productivity of the deposition process by the design of the first body element 12 and/or the second body element 18, as well as the sizing and spacing of the exit apertures 16, 22. When charge material is spent, or a materials change is required, the system 10 provides the above-discussed access port 56 for removal of either the second body element 18 from the first body element 12 (or deposition source structure), and/or the material 104 from the second body element 18, etc. Therefore, additional chemistry or different chemistry is more easily introduced into the system 10. The access port 56 is designed for the immediacy of removal from the deposition source structure and vacuum system 110 via without the requirement of decoupling electrical connections and other arduous tasks.

The system 10 of the present invention also decreases the maintenance required for the vacuum system 110, which improves productivity. Since higher levels of material utilization are provided in the presently-invented system 10, less material is wastefully deposited to deposition shielding and vacuum chamber surfaces. This allows for additional production to occur in place of the less frequently required maintenance duties.

Still further, the present invention describes methods of performing deposition processing and other associated tasks in the vacuum system 110, but provides for quick and easy removal of the components and subcomponents of the system 10 from the vacuum system 110. Quick resumption of the deposition process is enabled.

The present system 10 allows for high volume production compatibility and immediate removability of the components of the system 10, together with the functionalities of temperature feedback and emission flux profile shaping. The system 10 is capable of tailoring a user-desired emission coating profile, which increases the overall efficiency for industrial uses. The system 10 addresses film quality as a function of deposition rate and provides the user with an active and tunable emission profile, precision rate control and enhanced film quality to large substrate 100 areas. Therefore, desired emission patterns can be achieved, and material utilization efficiency is improved.

Still further, the present invention uses a heating process and a heating element 26 at increased voltage and reduced current. The heating element 26 is attached externally or internally, which allows for the ability to provide either light or only physical contact as a manner of providing the required power to the system 10. Either light connection to an electrical circuit (or no connection at all), eliminates the requirements for heavy gauge power connections to be firmly attached to the first body element 12 and/or the second body element 18 and/or the material 104. This enables the system 10 to allow for easy and efficient removability and/or interchangeability amongst the components and subcomponents.

The design of the first body element 12 and/or the second body element 18 provides a design that is easily rotatable with respect to each other or the substrate 100. This flexibility allows for the deposition process to be adjusted in order to deposit an infinite number of directions, such as outboard, slightly angled, sideways or downward. This rotatability further allows for aiming the source emissions in order to align the emitted material 106 with various substrate 100 positions, properly blend materials from multiple sources, as in the case of co-deposition or tri-deposition, or deliberately align or misalign the apertures 16, 22 to create appropriate physical effects of targeting to the substrate 100.

Delta pressure produces a slight differentiation in emission profile. Overall deposition uniformity from a 350 mm emission aperture 16, 22 upon a 300 mm substrate 100 is enhanced from 90% to 95% as delta pressure is increased between 1.0 angstrom per second and a 50 angstrom per second deposition rate respectively. The open emission hole area becomes a statistical baffle and shaper of the emitted material 106.

The system 10 of the present invention provides active control over the emission profile. In addition, the system 10 provides greater quality coated substrates 100. This, in turn, provides superior thin-film devices.

This invention has been described with reference to the preferred embodiments. Obvious modifications and alterations will occur to others upon reading and understanding the preceding detailed description. It is intended that the invention be construed as including all such modifications and alterations.

1. A material deposition system for depositing material onto a surface of a substrate, the system comprising:
a first body element having an interior cavity and at least one exit aperture extending through the first body element;
at least one second body element having an interior cavity and at least one exit aperture extending through the at least one second body element, the interior cavity of the at least one second body element configured to contain the material, wherein the at least one exit aperture of the at least one second body element is spatially separated from and in fluid communication with the at least one exit aperture of the first body element;
wherein at least one of the first body element and the at least one second body element are rotatable with respect to each other, such that the at least one exit aperture of the first body element and the at least one exit aperture of the second body element can be aligned and misaligned with respect to each other.

2. A material deposition system for depositing material onto a surface of a substrate, the system comprising:
at least one body element having an internal cavity configured to contain a material, a wall with a wall thickness and a substantially enclosed upper surface; and
a plurality of apertures extending through the upper surface of the at least one body element and forming a pattern along the upper surface, wherein the exit apertures have an open dimension (D) and a separation spacing (P), wherein the open dimension (D) and the separation spacing (P) are one of fixed and variable dimensions;
wherein the plurality of exit apertures have an open dimension (D) in the range of about ⅕ and about 5 times the wall thickness of the at least one body element;
wherein the plurality of exit apertures have a separation spacing (P) in the range of about 1.0 and about 20 times the open dimension (D) of the at least one body element.

3. The system of claim 2, wherein the at least one body element further comprises an access port for providing access to the inner cavity of the body element for inserting the material therein.

4. The system of claim 2, wherein the access port is positioned on an axial end of the at least one body element, the access port removably attachable to the axial end thereof.

5. The system of claim 2, further comprising a support fixture attached to at least one of an access port, an axial end of the at least one body element and the longitudinal surface of the at least one body element, the support fixture configured to provide at least one of reduced thermal conductance and separation of the at least one body element from further components of the material deposition system.

6. The system of claim 2, wherein the open dimension (D) of the plurality of exit apertures is in the range of about 0.03 cm and about 0.15 cm.

7. The system of claim 2, wherein the plurality of exit apertures have a total open hole area of less than about 1.0 cm² per 35.0 cm of body element length.

8. The system of claim 2, wherein a portion of the plurality of exit apertures include an open dimension (D) less than the wall thickness of the at least one body element.

9. The system of claim 2, further comprising a heating element configured to at least one of directly and indirectly heat the material contained in the at least one body element.

10. The system of claim 9, further comprising a temperature sensing probe in communication with the at least one body element and configured to sense the temperature of at least one of the body element and the material contained in the at least body element.

11. The system of claim 9, further comprising a process control apparatus in communication with at least one of the heating element, a temperature sensing probe and the at least one body element, wherein the process control apparatus provide temperature control of at least one of the body element and the material contained in the at least one body element.

12. The system of claim 2, wherein the plurality of exit apertures are at least one a variably spaced and variably sized with respect to each other.

13. The system of claim 2, wherein the plurality of exit apertures are positioned in order to provide a desired emission flux pattern and a desired coating profile on the substrate.

14. The system of claim 2, further comprising an emission sensing device configured to sense emission of material through the plurality of exit apertures, such that the rate of material volatilization from the at least one body element is determined.

15. The system of claim 2, further comprising a deposition sensing device configured to sense the deposition of material on the substrate, such that the rate of material volatilization from the at least one body element is determined.

16. The system of claim 2, wherein the at least one body element is at least one of rotatable and repositionable within the material deposition system.

17. A method of coating a substrate in a deposition material system having a crucible with a plurality of exit apertures extending therethrough, a deposition source structure and a vacuum system, the method comprising the steps of:
(a) positioning at least one of the deposition source structure and the crucible within the vacuum system;
(b) positioning at least one deposition chemistry element within the crucible;
(c) positioning at least one substrate in fluid communication with the deposition chemistry element;
(d) heating the deposition chemistry element to volatilize the deposition chemistry element and emit material;
(e) exposing at least a portion of the at least one substrate to material emitted from the heated deposition chemistry element through a plurality of exit apertures in operational communication with at least one of the deposition source structure and the crucible; and
(f) removing the crucible from the deposition source structure and vacuum system through at least one openable end of the deposition source structure.

18. The method of claim 17, further comprising the step of reintroducing the crucible into the deposition source structure and the vacuum system through the openable end of the deposition source structure, wherein the crucible contains at least one of deposition chemistry, an additional deposition chemistry element, a different deposition chemistry element and a further productive coating material element.

19. The method of claim 18, further comprising the steps of:
heating the at least one of the deposition chemistry, the additional deposition chemistry element, the different deposition chemistry element and the further productive coating material element to volatilize the deposition chemistry, the additional deposition chemistry element, the different deposition chemistry element and the further productive coating material element and emit material; and
exposing at least a portion of the at least one substrate to material emitted from the deposition chemistry, the additional deposition chemistry element, the different deposition chemistry element and the further productive coating element through the plurality of exit apertures.

20. The method of claim 17, further comprising the step of providing relative motion between emitted material and the at least one substrate, thereby providing a desired coating uniformity.

21. A method of thermally processing a deposition material in a crucible and a deposition source structure in a vacuum system, the method comprising the steps of:
(a) positioning at least one of the deposition source structure and the crucible within the vacuum system;
(b) positioning deposition material to be thermally processed in the crucible through an openable end of the deposition source structure and the crucible;
(c) heating the deposition material in a thermal processing procedure to at least one of process, clean, de-gas and fractionally distill the deposition material; and
(d) removing at least one of the deposition source structure and crucible from the vacuum system.

22. The method of claim 21, further comprising the steps of:
removing at least one of the deposition source structure and the crucible from the vacuum system; and
subsequently reintroducing the at least one of the deposition source structure and the crucible to the vacuum system, wherein the at least one of the deposition source structure and the crucible contains at least one of deposition chemistry, additional deposition material, different deposition material element and a further productive deposition material.

23. The method of claim 22, further comprising the step of heating the deposition chemistry, the additional deposition material, the different deposition material and the further productive coating material in a thermal processing procedure to at least one of process, clean, de-gas and fractionally distill the additional deposition material, the different deposition material element and the further productive deposition material.

24. A crucible for use in a material deposition system for depositing material onto a surface of a substrate, the crucible comprising:
at least one body element having an internal cavity configured to contain a material, a wall with a wall thickness and a substantially enclosed upper surface; and
a plurality of apertures extending through the upper surface of the at least one body element and forming a pattern along the upper surface, wherein the exit apertures have an open dimension (D) and a separation spacing (P), wherein the open dimension (D) and the separation spacing (P) are one of fixed and variable dimensions;
wherein the plurality of exit apertures have an open dimension (D) in the range of about ⅕ and about 5 times the wall thickness of the at least one body element;
wherein the plurality of exit apertures have a separation spacing (P) in the range of about 1.0 and about 20 times the open dimension (D) of the at least one body element.
